(19) United States
(12) Patent Application Publication
(10) Pub. No.: US 2007/0224808 A1
(43) Pub. Date: Sep. 27, 2007

(54) Silicided gates for CMOS devices

(75) Inventors: Tsung-Hsien Chang, Tai-Chung (TW); Tung-Heng Hsieh, Zhudong Town (TW); Chung-Cheng Wu, Hsin-Chu (TW); Shou Zen Chang, Hsinchu (TW)

Correspondence Address: SLATER & MATSIL, L.L.P., 17950 PRESTON ROAD, SUITE 1000, DALLAS, TX, 75252, US

(73) Assignee: Taiwan Semiconductor Manufacturing Company, Ltd.

(21) Appl. No.: 11/387,614

(22) Filed: Mar. 23, 2006

(51) Int. Cl. H01L 21/4763

(52) U.S. Cl. 438/649; 257/E21.622

(57) ABSTRACT

A silicided gate for CMOS transistors and a method of manufacture is provided. A gate electrode is formed on a substrate. A first dielectric layer is formed over the gate electrode and the substrate, and a second dielectric layer is formed over the first dielectric layer. The second dielectric layer is etched to form spacers adjacent the gate electrode. A treatment is performed on the first dielectric layer over the gate electrode, wherein the treatment increases the effective etch rate of the first dielectric layer as compared to untreated portions of the first dielectric layer. An etching procedure is then performed to expose the surface of the gate electrode, the etching procedure recessing the liner along sidewalls of the gate electrode. Thereafter, a silicide procedure is performed to silicide at least a portion of the gate electrode.

### TECHNICAL FIELD

The present invention relates generally to semiconductor devices, and more particularly, to silicided gates for complementary metal oxide-semiconductor transistors.

### BACKGROUND

Generally, complementary metal oxide-semiconductor (CMOS) transistors include a gate electrode and a gate dielectric, which are formed on a substrate (usually a silicon semiconductor substrate). Lightly doped drains are formed on opposing sides of the gate electrode by implanting N-type or P-type impurities into the substrate. An oxide liner and one or more implant masks (commonly referred to as spacers) are formed adjacent the gate electrode, and additional implants are performed to complete the source/drain regions. Current flowing through the source/drain regions may then be controlled by controlling the voltage levels applied to the gate electrode.

To increase switching speed and decrease contact resistance, the gate electrode and source/drain regions are often silicided. Typically, the gate electrode and source/drain regions are silicided by forming a metal layer over the gate electrode and source/drain regions and performing an anneal. The anneal causes the metal layer to react with the silicon, thereby forming a silicide layer on the gate electrode and source/drain regions.

In some situations, it is desirable to create a thicker silicide region, particularly on the gate electrode. One method of forming a thicker silicide region is to selectively etch the oxide liner to expose a greater portion of the gate electrode along the sidewalls. This selective etch, however, tends to also remove a portion of the oxide liner below the spacers, which may adversely affect the doping profile in subsequent steps.

Another method that has been used to silicide a greater portion of the gate electrode is to reduce the height of the spacers, thereby exposing more of the sidewalls of the gate electrode. By reducing the height of the spacers, however, the thickness of the spacers is also reduced. The reduced thickness of the spacer alter the doping profile of the source/drain regions, which may adversely affect the desired performance of the transistor.

Accordingly, there is a need for transistor, and a method of manufacture thereof, having a greater silicided region.

### SUMMARY OF THE INVENTION

These and other problems are generally reduced, solved or circumvented, and technical advantages are generally achieved, by embodiments of the present invention, which provides silicided gate electrode for CMOS transistors.

In an embodiment of the present invention, a silicided gate electrode for CMOS transistors and a method of manufacture is provided. Generally, the liner, such as an oxide liner, between the implant masks and the gate electrode is recessed, thereby allowing a greater portion of the gate electrode to be silicided in subsequent processing steps.

In an embodiment, the silicided gate electrode may be formed by depositing a first dielectric layer over the gate electrode and the substrate, and depositing a second dielectric layer over the first dielectric layer. The second dielectric layer is etched to form spacers adjacent the gate electrode. A treatment is performed on the first dielectric layer over the gate electrode, wherein the treatment increases the effective etch rate of the first dielectric layer as compared to untreated portions of the first dielectric layer. An etching procedure is then performed to expose the surface of the gate electrode and to recess the liner along sidewalls of the gate electrode. Thereafter, a silicide procedure is performed to silicide at least a portion of the gate electrode.

In an embodiment, the treatment may be performed by implanting ions, such as fluorine, carbon, germanium, or the like ions.

It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1-8 are cross-sectional views of a wafer after various process steps are performed in accordance with an embodiment of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

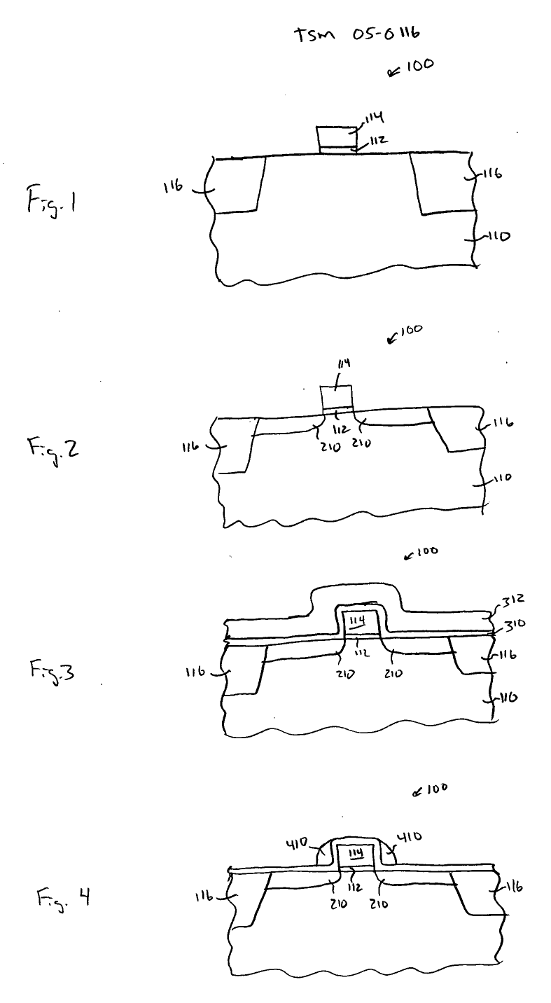

FIGS. 1-8 illustrate an embodiment for fabricating a transistor (e.g., an NMOS or a PMOS transistor) using a recessed liner between an implant mask and a gate electrode in accordance with an embodiment of the present invention. As one of ordinary skill in the art will appreciate, recessing the liner between the implant mask and gate electrode allows a larger portion of the gate electrode to be silicided without adversely affecting other operational characteristics of the transistor. For example, by recessing the liner in accordance with embodiments of the present invention, undercutting of the liner between the implant mask and the substrate may be reduced and/or prevented while allowing a greater portion of the gate electrode to be silicided. Furthermore, the size of the implant mask does not need to be altered.

It should be noted that the doping profile to form the transistor is provided for illustrative purposes only and that other doping profiles may be used. For example, a plurality of implant masks may be used to form each of the source/drain regions. In other embodiments, it may be desirable to utilize halo and/or pocket implants to form the source/drain regions.

Embodiments of the present invention may be used in a variety of circuits. For example, embodiments of the present invention may be useful in I/O devices, core devices, memory circuits, system-on-chip (SoC) devices, other integrated circuits, and the like.

Referring first to FIG. 1, a wafer 100 is shown having a substrate 110 with a gate dielectric 112 and a gate electrode 114 formed thereon in accordance with an embodiment of the present invention. In an embodiment, the substrate 110 comprises a P-type bulk silicon substrate. Other materials, such as germanium, silicon-germanium alloy, or the like, could alternatively be used for the substrate 110. The substrate 110 may also be an active layer of a semiconductor-on-insulator (SOI) substrate or a multi-layered structure such as a silicon-germanium layer formed on a bulk silicon layer. The substrate may have P-wells (not shown) and/or N-wells (not shown) formed therein to provide further isolation for NMOS devices and PMOS devices, respectively.

The gate dielectric 112 and the gate electrode 114 may be formed by depositing and patterning a dielectric layer and a conductive layer over the substrate 110. The dielectric layer preferably comprises a dielectric material, such as silicon dioxide, silicon oxynitride, silicon nitride, a high-K metal oxide, a combination thereof, or the like. A silicon dioxide dielectric layer may be formed, for example, by an oxidation process, such as wet or dry thermal oxidation, or by a chemical vapor deposition (CVD) process. In the preferred embodiment, the dielectric layer is about 10 Å to about 40 Å in thickness.

The conductive layer comprises a conductive material, such as a metal (e.g., tantalum, titanium, molybdenum, tungsten, platinum, aluminum, hafnium, ruthenium), a metal silicide (e.g., titanium silicide, cobalt silicide, nickel silicide, tantalum silicide), a metal nitride (e.g., titanium nitride, tantalum nitride), doped poly-crystalline silicon, other conductive materials, or a combination thereof. In one example, amorphous silicon is deposited and re-crystallized to create poly-crystalline silicon (poly-silicon). In the preferred embodiment in which the gate electrode is poly-silicon, the gate electrode 114 may be formed by depositing doped or undoped poly-silicon by low-pressure CVD (LPCVD) to a thickness in the range of about 200 Å to about 2000 Å, but more preferably about 1000 Å.

The gate dielectric 112 and the gate electrode 114 may be patterned by photolithography techniques as are known in the art. Generally, photolithography involves depositing a photoresist material, which is then masked, exposed, and developed. After the photoresist mask is patterned, an anisotropic etching process may be performed to remove unwanted portions of the dielectric layer and the conductive layer to form the gate dielectric 112 and the gate electrode 114, respectively, as illustrated in FIG. 1.

Shallow-trench isolations (STIs) 116, or some other isolation structures such as field oxide regions, may be formed in the substrate 110 to isolate active areas on the substrate. The STIs 116 may be formed by etching trenches in the substrate and filling the trenches with a dielectric material, such as silicon dioxide, a high-density plasma (HDP) oxide, or the like, as known in the art.

FIG. 2 illustrates the wafer 100 of FIG. 1 after first implant regions 210 have been formed in accordance with an embodiment of the present invention. The first implant regions 210 form lightly-doped drain (LDD) regions. The first implant region 210 may be doped with, for example, an N-type dopant, such as arsenic ions at a dose of about 8E14 to about 1.5E15 atoms/cm² and at an energy of about 1 to about 3 KeV, to form an NMOS device, or a P-type dopant, such as BF₂ ions at a dose of about 7E14 to about 9E14 atoms/cm² and at an energy of about 2 to about 3 KeV to form a PMOS device. Other types of dopants may be used.

FIG. 3 illustrates the wafer 100 of FIG. 2 after a first dielectric layer 310 and a second dielectric layer 312 have been formed in accordance with an embodiment of the present invention. The first dielectric layer 310 preferably comprises silicon dioxide formed by LPCVD techniques using TEOS and oxygen as a precursor. In the preferred embodiment, the first dielectric layer 310 is about 10 Å to about 200 Å in thickness, but more preferably about 180 Å in thickness.

The second dielectric layer 312 preferably comprises a nitrogen-containing layer, such as silicon nitride (Si₃N₄) that has been formed using CVD techniques using silane and ammonia as precursor gases. In the preferred embodiment, the second dielectric layer 312 is about 500 Å to about 650 Å in thickness. Other materials and processes may be used for the first dielectric layer 310 and the second dielectric layer 312. However, it should be noted that it is preferred that a high-etch selectivity exists between the materials used to form the first dielectric layer 310 and the second dielectric layer 312.

FIG. 4 illustrates the wafer 100 of FIG. 3 after the second dielectric layer 312 (FIG. 3) is patterned to form spacers 410 in accordance with an embodiment of the present invention. The spacers 410 may be patterned by performing an isotropic or anisotropic etch process, such as an isotropic etch process using a solution of phosphoric acid (H₃PO₄) wherein the first dielectric layer 310 acts as an etch-stop. Because the thickness of the layer of Si₃N₄ (or other material) is greater in the regions adjacent to the gate electrode 114, the isotropic etch removes the Si₃N₄ material except for that material adjacent the gate electrode 114, thereby forming the spacers 410 as illustrated in FIG. 4.

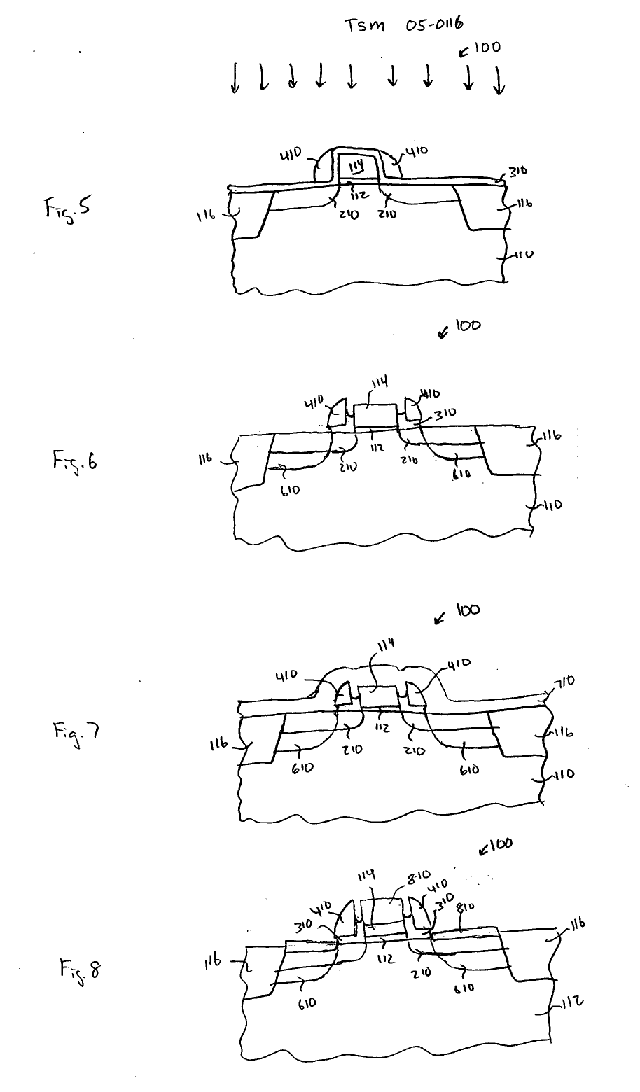

FIG. 5 illustrates the wafer 100 of FIG. 4 after treating exposed portions of the first dielectric layer 310 in accordance with an embodiment of the present invention. It has been found that the first dielectric layer 310 may be treated to increase its effective etching rate. The increased etching rate allows the first dielectric layer 310 positioned between the spacers 410 and the gate electrode 114 to be recessed.

In an embodiment, the first dielectric layer 310 may be treated by implantation. It has been found that implanting ions into the first dielectric layer 310 may damage the first dielectric layer 310, thereby altering the etch rate of the first dielectric layer 310. In this embodiment, exposed portions of the first dielectric layer 310 over the substrate 110 and the gate electrode 114 are implanted with ions that increase its etch rate. It should be noted that spacers 410 protect the portion of the first dielectric layer 310 between the spacers 410 and the substrate 110 during the implant process. In this manner, the etch rate of the first dielectric layer 310 located between the spacers 410 and the substrate 110 is substantially unaffected. As a result, the first dielectric layer 310 positioned between the spacers 410 and the gate electrode 114 will exhibit a higher etch rate, thereby creating a recess and exposing a larger portion of the gate electrode 114.

In an embodiment, the implanting process comprises implanting fluorine ions at a dose of about 1E14 to about 5E14 atoms/cm² and at an energy of about 7 to about 11 KeV. Alternatively, other types of ions may be used, such as germanium, carbon, or other ions that damage the structure of the first dielectric layer 310, or otherwise increases the effective etch rate, may be used.

FIG. 6 illustrates the wafer 100 of FIG. 5 after the first dielectric layer 310 has been etched and second implant regions 610 have been formed in accordance with an embodiment of the present invention. An etching process that may be used is a wet dip in dilute hydrofluoric (HF) acid. Dilute hydrofluoric acid may, for example, be formed by a mixture of 1 part of concentrated (49%) hydrofluoric acid and 25 parts of water (H₂O). This mixture is commonly known as 25:1 HF. Other etching processes and/or solutions may be used.

As illustrated in FIG. 6, embodiments of the present invention may be used to recess the first dielectric layer 310 below a top surface of the gate electrode 114 with little or no undercutting of the first dielectric layer 310 below the spacers 410. Recessing the first dielectric layer 310 will allow a greater portion of the gate electrode 114 to be silicided in subsequent processing steps, and limiting or preventing undercutting the first dielectric layer 310 below the spacers, possibly adversely affecting the performance of the transistors. The amount of recess is preferably between about 350 Å and 500 Å, but more preferably about 400 Å, from the top surface of the poly-silicon gate prior to silicidation process. It should be noted that untreated portions of the first dielectric layer 310, such as the portion of the first dielectric layer 310 between the spacers 410 and the substrate 110, is etched at a slower rate. Thus, while a small recess may be formed in the first dielectric layer 310 between the spacers 410 and the substrate 110, the recess will be smaller than the recess formed in the first dielectric layer 310 adjacent the gate electrode 114.

It should also be noted that different spacers and doping profiles may be used, and that different doping profiles may be used for the NMOS and PMOS transistors. For example, additional spacers and implants may be used to form the source/drain regions for the NMOS transistors and/or the PMOS transistors.

The second implant regions 610 form heavily-doped drain regions for an NMOS and/or PMOS transistor. The second implant regions 610 may be doped with, for example, phosphorous ions at a dose of about 1E15 to about 3E15 atoms/cm² and at an energy of about 4 to about 6 KeV to form an NMOS device, or boron ions at a dose of about 1E15 to about 3E15 atoms/cm² and at an energy of about 1 to about 2 KeV to form a PMOS device. Other types of ions, doses, energy levels, and the like may be used.

FIG. 7 illustrates the wafer 100 of FIG. 6 after forming a metal layer 710 and performing a silicidation process in accordance with an embodiment of the present invention. The silicidation process may be used to decrease the contact resistance between contact plugs (not shown) and source/drain regions and the gate electrode 114. Generally, the silicidation process involves forming the metal layer 710, such as a nickel-based layer, cobalt-based layer, or the like, via plasma vapor deposition (PVD) procedures. An anneal procedure causes the metal layer 710 to react with the gate electrode 114 and the source/drain regions to form a metal silicide, e.g., nickel silicide, cobalt silicide, or the like. Portions of the metal layer overlying the spacers 410 remain unreacted. Selective removal of the unreacted portions of the metal layer 710 may be accomplished, for example, by wet etch procedures. An additional anneal cycle may be used if desired to alter the phase of silicide regions, which may result in a lower resistance. FIG. 8 illustrates silicidation regions 810 of the resulting structure after the silicidation process has been performed. The silicided region 810 of the gate electrode 114 is preferably greater than about 400 Å, but more preferably is about 500 Å, in thickness.

Thereafter, standard processing techniques may be used to complete fabrication of the semiconductor device. For example, inter-layer dielectrics may be formed, contacts and vias may be formed, metal lines may be fabricated, and the like.

As one of ordinary skill in the art will appreciate, embodiments of the present invention provide several advantages. For example, by forming a recess in the liner formed between the spacer and the gate electrode, the gate electrode may have a greater area silicided, which may reduce the contact resistance. This may be accomplished without significantly undercutting the liner from under the spacers or causing significant reduction in the height (and width) of the spacers. As a result, the gate electrode may be silicided to a greater extent without substantially affecting the source/drain regions.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of forming a semiconductor device, the method comprising:
providing a substrate;
forming a gate electrode over the substrate, the gate electrode having a top and sidewalls;
forming a liner over the gate electrode and the substrate;
forming spacers adjacent the gate electrode on the liner;
treating exposed portions of the liner, the treating increasing an etch rate of treated portions of the liner in comparison to untreated portions of the liner;
removing the liner on the top of the gate electrode and at least a portion of the liner on the sidewalls of the gate electrode; and
siliciding at least a portion of the gate electrode.

2. The method of claim 1, wherein the treating is performed in part by implanting ions into exposed portions of the liner.

3. The method of claim 2, wherein the ions comprise ions of fluorine, germanium, carbon, or a combination thereof.

4. The method of claim 1, wherein the removing exposes more than about 400 Å of the sidewall of the gate electrode.

5. The method of claim 1, wherein the removing is performed by a wet dip in hydrofluoric acid.

6. The method of claim 1, wherein the siliciding causes at least 500 Å of the gate electrode to be silicided.

7. The method of claim 1, wherein the liner comprises an oxide.

8. A method of forming a semiconductor device, the method comprising:
providing a substrate;
forming a gate electrode over the substrate, the gate electrode having a top and sidewalls;
forming a first dielectric layer over the gate electrode and the substrate;
forming spacers adjacent the gate electrode on the first dielectric layer;
recessing the first dielectric layer adjacent the gate electrode, the first dielectric layer being recessed at least 400 Å from the top of the gate electrode and the first dielectric layer under the spacers being recessed less than the liner adjacent the gate electrode; and
siliciding at least a portion of the gate electrode.

9. The method of claim 8, wherein the recessing comprises:
implanting ions into the first dielectric layer on the top of the gate electrode, the ions increasing the etch rate of the first dielectric layer; and
etching the first dielectric layer on the top of the gate electrode and at least a portion of the first dielectric layer along the sidewalls of the gate electrode.

10. The method of claim 9, wherein the ions comprise fluorine, germanium, carbon, or a combination thereof.

11. The method of claim 8, wherein the siliciding causes at least 500 Å of the gate electrode to be silicided.

12. The method of claim 8, wherein the recessing is performed at least in part by a wet dip in hydrofluoric acid.

13. The method of claim 8, wherein the spacers comprise a nitrogen-containing material or a carbon-containing material.

14. The method of claim 8, wherein the first dielectric layer comprises an oxide.

15. A method of forming a semiconductor device, the method comprising:
providing a substrate;
forming a gate electrode over the substrate, the gate electrode having a top and sidewalls;
forming a first dielectric layer over the gate electrode and the substrate;
forming a second dielectric layer over the first dielectric layer;
removing a portion of the second dielectric layer, thereby exposing the first dielectric layer on the top of the gate electrode, remaining portions of the second dielectric layer forming spacers adjacent the gate electrode;
treating exposed portions of the first dielectric layer on top of the gate electrode;
etching the exposed portions of the first dielectric layer on top of the gate electrode, the etching recessing the first dielectric layer along the sidewalls of the gate electrode; and
siliciding at least a portion of the gate electrode.

16. The method of claim 15, wherein the treating comprises implanting ions into first dielectric layer on the top of the gate electrode.

17. The method of claim 16, wherein the ions comprise fluorine, germanium, carbon, or a combination thereof.

18. The method of claim 15, wherein the etching exposes more than about 400 Å of the sidewall of the gate electrode.

19. The method of claim 15, wherein the etching is performed at least in part by a wet dip in hydrofluoric acid.

20. The method of claim 15, wherein the siliciding causes at least 500 Å of the gate electrode to be silicided.
